(19) United States
(12) Patent Application Publication
(10) Pub. No.: US 2025/0211191 A1
(43) Pub. Date: Jun. 26, 2025

(54) VOLUME ACOUSTIC DEVICE AND METHOD FOR PRODUCING A VOLUME ACOUSTIC DEVICE

(71) Applicant: Robert Bosch GmbH, Stuttgart (DE)

(72) Inventor: Christoph Schelling, Stuttgart (DE)

(21) Appl. No.: 18/848,320

(22) PCT Filed: Apr. 19, 2023
(86) PCT No.: PCT/EP2023/060139

§ 371 Date: Sep. 18, 2024

(30) Foreign Application Priority Data
Apr. 25, 2022 (DE) 10 2022 203 972.6

(51) Int. Cl. H03H 9/02; H03H 3/02; H03H 9/13; H03H 9/17

(52) U.S. Cl. CPC H03H 9/02102; H03H 3/02; H03H 9/02133; H03H 9/02149; H03H 9/131; H03H 9/173; H03H 9/178

(57) ABSTRACT

A volume acoustic device. The volume acoustic device includes a first electrode and a second electrode and a piezoelectric element disposed between the first electrode and the second electrode. The piezoelectric element is configured such that a first electromagnetic signal fed into the first electrode is converted to an acoustic signal in the piezoelectric element, and the acoustic signal is converted back into a second electromagnetic signal in the second electrode. A dielectric layer surrounds the first electrode, the second electrode, and the piezoelectric element, and has a substantially planar surface. At least one separation trench at least partially surrounds the piezoelectric element is formed in the dielectric layer.

### FIELD

The present invention relates to a volume acoustic device and method for producing a volume acoustic device.

### BACKGROUND INFORMATION

Bulk acoustic wave (BAW) components are used in high-frequency technology as resonators in filters and oscillators. The working frequency of the components is primarily determined by the layer thickness of the piezoelectric layer and the speed of sound in the piezoelectric material. To achieve higher working frequencies, the layer thickness has to be reduced. The tolerances are therefore becoming more and more important.

As the layer thickness of the piezoelectric material decreases, the capacitance of the BAW component increases. To then be able to maintain the wave impedance, the component surface has to be reduced as well. Acoustic energy is lost at the edge of the component, however. The edge losses increase quadratically with the working frequency as the size of the component is reduced. The technology of conventional BAW components (BAW) therefore reaches its limits at around 10 GHZ.

A BAW component, in which the capacitance can be kept low even at higher operating frequencies by stacking two different piezo materials with opposite polarity, so that the edge losses decrease and higher working frequencies in the millimeter wave range can be realized, is described in U.S. Patent Application Publication Nos. US 2018/085787 A1 and US2013/193808 A1.

### SUMMARY

The present invention provides a volume acoustic device and a method for producing a volume acoustic device.

Preferred embodiments of the present invention are disclosed herein.

According to a first aspect, the present invention therefore relates to a volume acoustic device. According to an example embodiment of the present invention, the volume acoustic device includes a first electrode and a second electrode and a piezoelectric element disposed between the first electrode and the second electrode, wherein the piezoelectric element is configured such that a first electromagnetic signal fed into the first electrode is converted to an acoustic signal in the piezoelectric element, and the acoustic signal is converted back into a second electromagnetic signal in the second electrode. a dielectric layer (7) which surrounds the first electrode (1a, 1b), the second electrode (2a, 2b) and the piezoelectric element (3) and has a substantially planar surface, wherein at least one separation trench (11a, 11b) that at least partially surrounds the piezoelectric element (3) is formed in the dielectric layer (7).

According to a second aspect, the present invention relates to a method for producing a volume acoustic device. According to an example embodiment of the present invention, this involves providing a substrate. A first electrode and a second electrode and a piezoelectric element disposed between the first electrode and the second electrode are furthermore disposed on the substrate, wherein the piezoelectric element is configured such that a first electromagnetic signal fed into the first electrode is converted to an acoustic signal in the piezoelectric element, and the acoustic signal is converted back into a second electromagnetic signal in the second electrode. A dielectric layer which surrounds the first electrode, the second electrode and the piezoelectric element and has a substantially planar surface is formed as well. Also, at least one separation trench that at least partially surrounds the piezoelectric element is formed in the dielectric layer.

According to an example embodiment of the present invention, the volume acoustic device comprises a piezoelectric element which serves as an element of a resonator core. The resonator core is surrounded by a dielectric. To limit disruptive parasitic capacitances caused by an overlap of leads and electrodes, the device has a substantially planarized surface. Without separation trenches, dissipation losses of acoustic energy would occur on the periphery via the dielectric, which would result in undesirable, higher insertion losses. The chip could moreover be bent by stress coupling from the outside, or bend by itself due to the temperature which would indirectly couple stress into the resonator core via the dielectric. This could lead to a shift in the resonance frequency of the resonator or the passband edges of the filter component (temperature drift).

According to an example embodiment of the present invention, therefore, at least one separation trench is introduced into the dielectric surrounding the resonator core, which then also serves as an acoustic isolation trench and stress-decoupling trench. On the one hand, this makes it possible to reduce the stress coupling to the resonator core. On the other hand, the acoustic energy around the resonator core is locked in and cannot be lost, because acoustic waves cannot pass through the separation trench due to the high acoustic impedance difference at the dielectric/air or dielectric/vacuum interface. Thirdly, much as is the case with the lateral shape of the resonator core, unwanted spurious modes can be better suppressed via the shape and position of the at least one isolation trench. The volume acoustic device according to the present invention thus minimizes the acoustic energy losses and thermal drift effects while maintaining robustness with respect to environmental influences. Lower insertion losses and less acoustic crosstalk between adjacent volume acoustic devices on a (filter) chip are moreover achieved.

According to one example embodiment of the volume acoustic device of the present invention, the separation trenches are implemented as wall-shaped and/or column-shaped recesses in the dielectric, wherein at least the plane of the piezoelectric resonator core is included.

According to one example embodiment of the volume acoustic device according to the present invention, the at least one separation trench surrounds the piezoelectric element completely.

According to one example embodiment of the present invention, the volume acoustic device comprises at least one lead to the first electrode and/or the second electrode, wherein the at least one lead passes under or over the at least one separation trench.

According to one example embodiment of the volume acoustic device of the present invention, the at least one separation trench is spanned by a membrane, wherein a lead to the first electrode and/or the second electrode is formed in the membrane. The separation trench can therefore also completely encircle the resonator core.

According to one example embodiment of the volume acoustic device of the present invention, a cavity is formed under the second electrode, wherein the cavity is fluidically connected to the separation trench. The separation trench can thus enable pressure equalization between the cavity and the surroundings.

According to one example embodiment of the volume acoustic device of the present invention, the at least one separation trench is provided at least partly with a passivation layer. The passivation layer protects against the absorption of moisture and can prevent premature chemical aging. The passivation layer advantageously has a layer thickness that corresponds to one quarter of the acoustic wavelength of the central pass frequency of the resonator core in the passivation material.

According to one example embodiment of the volume acoustic device of the present invention, a large number of the volume acoustic devices serving as resonators can be suitably connected in circuits to form so-called conductor and/or grating configurations. This makes it possible to create filter components that are permeable to defined frequency ranges and can be designed for any frequency band, for example in mobile communications. These filters can be used to prevent signal interference between transmitting and receiving channels both in the communication modules of the mobile terminals and in the base stations.

Higher frequencies necessitate smaller layer thicknesses, which, for example, leads to more stringent requirements in terms of layer thickness accuracy. The lateral dimensions of the resonators traditionally had to be scaled down at the same time as the decreasing layer thickness in order to compensate the increase in capacitance caused by the reduction in the layer thickness and to be able to maintain the target impedance value of, for example, 500. This reduction in size would result in higher acoustic energy losses, however, because the ratio of the periphery to the surface area of the resonators increases.

According to one example embodiment of the volume acoustic device of the present invention, therefore, the piezoelectric element comprises at least two piezoelectric layers with the same polarity and at least one intermediate layer disposed between the at least two piezoelectric layers. Acoustic layer thicknesses of the piezoelectric layers and the intermediate layer all correspond to an odd multiple (1×, 3×, . . . ) of half the acoustic wavelength of an acoustic signal to be transmitted. The capacitance is thus reduced by inserting at least one additional intermediate layer and a further piezoelectric layer. The insertion of the additional piezoelectric layer and the at least one intermediate layer corresponds to a series connection of additional series capacitances, which can now individually assume larger values because, when connected in series, the reciprocal values of the individual capacitances add up to the reciprocal total capacitance. The resonators can thus be dimensioned laterally larger than would be the case without intermediate layers. This results in lower edge losses, and the resonators can be designed and used for higher frequencies. In order to not destroy the resonance, the total acoustic layer thickness of the intermediate layer is adapted to the acoustic target wavelength in the intermediate layer. The total acoustic layer thickness of the piezoelectric element thus corresponds to an odd multiple (1×, 3×, . . . ) of half the acoustic wavelength.

The at least one further piezoelectric layer disposed on the second electrode serves to efficiently convert the acoustic wave back into an electromagnetic wave at the second electrode.

The volume acoustic device of the present invention makes it possible to open up higher frequency ranges with improved behavior in terms of thermal drift. An (incoming) high frequency signal can be fed to the first electrode of the volume electric device. The high-frequency signal is a first electromagnetic wave, which is converted by the piezoelectric element to an acoustic wave at the first electrode and back into a second electromagnetic wave at the opposite second electrode. For a given electromagnetic or acoustic frequency, the acoustic wavelength λₐ is determined using the speed of sound cₛ of the respective layer material according to the following formula:

$${λ}_{a} = {c}_{s} / f .$$

If the acoustic layer thicknesses dₚ of the piezoelectric layers and the intermediate layer stack correspond to a multiple (1×, 3×, . . . ) of half the acoustic wavelength of the converted electromagnetic wave (i.e. it acoustic signal), i.e.:

$${d}_{p} = ( n + \frac{1}{2} ) * {λ}_{a}$$

for n={0, 1, . . . }, the incoming signal is transmitted or reflected. The volume acoustic device can thus serve as a volume acoustic resonator.

According to another example embodiment of the present invention, the volume acoustic device comprises a plurality of piezoelectric layers, wherein one intermediate layer is disposed between each two successive piezoelectric layers.

According to another example embodiment of the volume acoustic device of the present invention, the intermediate layer is formed by a single layer. The acoustic layer thickness of the single layer corresponds to an odd multiple (1×, 3×, . . . ) of half the acoustic wavelength of the acoustic signal to be transmitted, i.e. the target wavelength.

According to another example embodiment of the volume acoustic device of the present invention, the at least one intermediate layer consists of a plurality of sublayers, wherein the sum of acoustic layer thicknesses of the sublayers corresponds to an odd multiple (1×, 3×, . . . ) of half the acoustic wavelength of the acoustic signal to be transmitted. For instance, the intermediate layer comprises two sublayers with the wavelengths:

$${λ}_{a} / 4 + {λ}_{a} / 4 = {λ}_{a} / 2$$

$$or :$$

$${λ}_{a} / 4 + 5 {λ}_{a} / 4 = 3 {λ}_{a} / 2$$

$$or :$$

$$3 {λ}_{a} / 4 + 3 {λ}_{a} / 4 = 3 {λ}_{a} / 2.$$

In each case, the first summand indicates the acoustic layer thickness of the first sublayer and the second summand indicates the acoustic layer thickness of the second sublayer. The principle can, however, also analogously be applied to more than two sublayers.

According to another example embodiment of the volume acoustic device of the present invention, the acoustic layer thicknesses of the piezoelectric layers and the intermediate layer each correspond to half the acoustic wavelength of the acoustic signal to be transmitted. In other words, according to the present invention, the total acoustic layer thickness of the piezoelectric element is then 3·λₐ/2. This results in a fundamental resonance (i.e. n=0, lowest order) in the intermediate layer and in the piezoelectric layers. This is advantageous because then the highest quality factors occur, the filter edges can be particularly steep and the insertion losses can be particularly small.

According to another example embodiment of the volume acoustic device of the present invention, a material of the intermediate layer comprises dielectrics such as silicon oxide, silicon nitride, silicon carbide, aluminum oxide or DLC (diamond-like carbon). Preferred materials exhibit intrinsically low dielectric and/or acoustic attenuation and an adapted coefficient of thermal expansion.

According to another example embodiment of the volume acoustic device of the present invention, the at least one intermediate layer has a multilayered structure, for example consisting of acoustic Bragg reflector layers with odd multiples (1×, 3×, . . . ) of λₐ/4 layer thicknesses. Suitable material pairs for reflector layers are characterized by differences in the speed of sound of the materials and low material attenuation. Possible materials are, for example, Ti, Ta or Cu for low speeds of sound or Al, Ni, W or Mo for high speeds of sound.

According to another example embodiment of the volume acoustic device of the present invention, combinations of dielectric and semiconducting and/or metallic layers are provided as an intermediate layer or as intermediate layers.

According to another example embodiment of the volume acoustic device of the present invention, the above-described different intermediate layers can occur together in any combination. The piezoelectric element can comprise more than two piezoelectric layers and more than one intermediate layer, for instance. In that case, at least one of the intermediate layers can be made of a single layer with an odd-numbered Δₐ/2 layer thickness and at least one further intermediate layer can be made of multilayered acoustic Bragg reflector layers with odd multiples (1×, 3×, . . . ) of Δₐ/4 layer thicknesses.

According to another example embodiment of the volume acoustic device of the present invention, a material of the piezoelectric layer includes AlN or ScAlN. This is advantageous because of the high speed of sound, which permits a comparatively large layer thickness. Other possible materials are ZnO₂, LiNbO₃ or LiTaO₃.

According to another example embodiment of the volume acoustic device of the present invention, the first electrode and/or the second electrode are configured as acoustic Bragg reflectors, as already described above for the intermediate layer. A Bragg reflector layer can be inserted between the substrate and the piezoelectric element, which makes it possible to prevent a loss of acoustic energy into the substrate in order to keep insertion losses small. This an SMR (solidly mounted resonator) architecture. Due to the good temperature coupling to the substrate, the SMR architecture can advantageously be used in applications in which high power has to be processed, e.g. in base stations and in the transmission path of a mobile radio device.

According to another example embodiment of the volume acoustic device of the present invention, the first and/or second electrode (and thus the piezoelectric element) is underetched. This is a FBAR (film bulk acoustic resonator) architecture. In this case, the acoustic wave is reflected at the electrode/air interface, which is why the FBAR architecture exhibits low insertion losses. This is favorable for greater bandwidths and for the receiving path in the mobile radio device.

According to another example embodiment of the present invention, the volume acoustic device can be used as a highly precise timing oscillator, in filter components for frequencies in the GHz range (in particular also >10 GHZ), or as a gravimetric resonance sensor. The volume acoustic device can in particular be used for high-frequency systems, such as in the mobile radio range (20 GHz-100 GHz) or radar range.

Further advantages, features and details of the present invention will emerge from the following description, in which different embodiment examples of the present invention are described in detail with reference to the figures.

### BRIEF DESCRIPTION OF THE DRAWINGS

FIG. 1 shows a schematic cross-sectional view of a volume acoustic device according to one example embodiment of the present invention.

FIG. 2 shows a schematic plan view onto a chip with volume acoustic devices shown in FIG. 1.

FIG. 3 shows a schematic cross-sectional view of a volume acoustic device according to another example embodiment of the present invention.

FIG. 4 shows a schematic plan view onto a chip with volume acoustic devices shown in FIG. 3.

FIG. 5 a schematic cross-sectional view of a volume acoustic device according to another embodiment of the present invention.

FIG. 6 shows a schematic plan view onto a chip with volume acoustic devices shown in FIG. 5.

FIG. 7 shows a flow chart of a method for producing a volume acoustic device according to one example embodiment of the present invention.

In all figures, identical or functionally identical elements and apparatuses are provided with the same reference sign. The numbering of method steps is for the sake of clarity and is generally not intended to imply a specific chronological order. It is in particular also possible to carry out multiple method steps at the same time.

### DETAILED DESCRIPTION OF EXAMPLE EMBODIMENTS

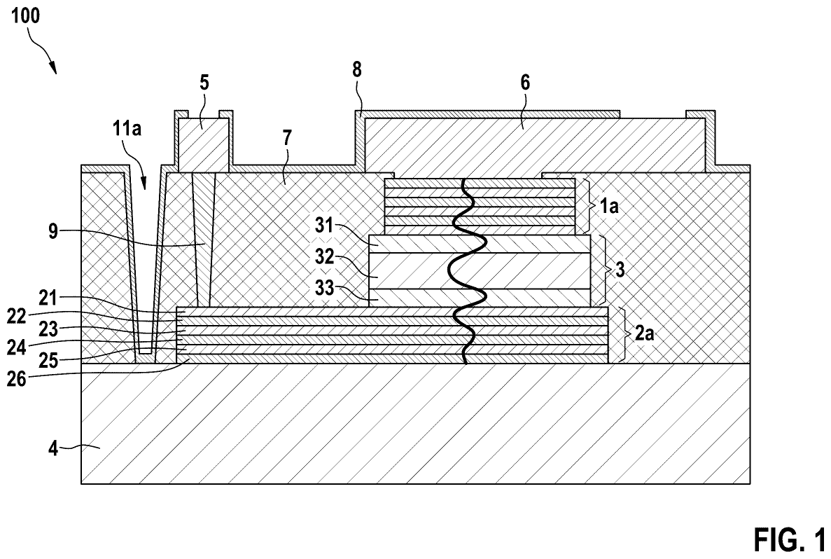

FIG. 1 shows a cross-sectional view of a volume acoustic device 100. The volume acoustic device 100 comprises a substrate 4 on which a second acoustic Bragg reflector 2a is disposed. This comprises a plurality of sublayers 21 to 26 having alternately high and low speeds of sound or acoustic impedance. A first acoustic Bragg reflector 1a is provided as well, which can be similarly structured.

The first Bragg reflector 1a consists of an electrically conductive material and serves as the first electrode and the second Bragg reflector 2a likewise consists of an electrically conductive material and serves as the second electrode.

A piezoelectric element 3 is disposed between the second Bragg reflector 2a and the first Bragg reflector 1a. A first electromagnetic signal fed into the first Bragg reflector 1a via a first lead 6 is converted to an acoustic signal in the piezoelectric element 3 during operation. The acoustic signal is then converted into a second electromagnetic signal in the second Bragg reflector 2a and, if an acoustic resonance condition is met, output via a through-contact 9 and a second lead 5.

The piezoelectric element 3 comprises two substantially identical piezoelectric layers 31, 33 with the same polarity and an intermediate layer 32 disposed between the two piezoelectric layers 31, 33. Acoustic layer thicknesses of the piezoelectric layers 31, 33 and the intermediate layer 32 all correspond to an odd multiple (1×, 3×, . . . ) of half the acoustic wavelength of an acoustic signal to be transmitted, i.e. a predetermined acoustic wavelength (corresponding to a predetermined pass frequency of the volume acoustic device). Preferably, half the acoustic wavelength of the desired pass frequency fits into the piezoelectric layers 31, 33 and into the intermediate layer 32 as a fundamental first resonance of the piezoelectric element 3 (see indicated wave).

The through-contact 9 and the resonator core consisting of the first Bragg reflector 1a, the second Bragg reflector 2a and the piezoelectric element 3 are surrounded by a dielectric layer 7, which has a substantially planar surface. A passivation layer 8 is disposed on the leads 5, 6 and the dielectric layer 7. A separation trench 11a, the surface of which is likewise covered by the passivation layer, is formed in the dielectric layer 7.

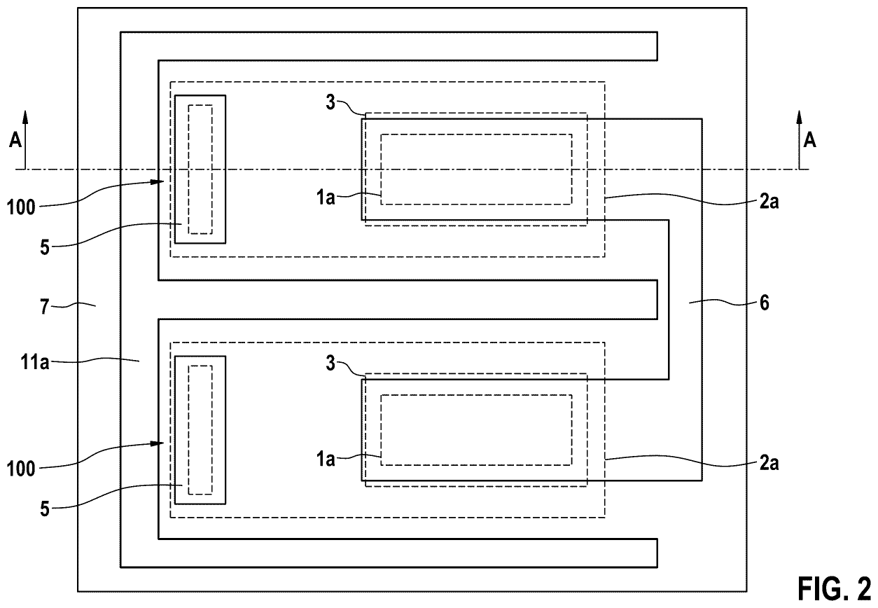

FIG. 2 shows a schematic plan view onto a chip with two of the volume acoustic devices 100 shown in FIG. 1. FIG. 1 corresponds to a sectional view along the plane A-A. As can be seen in FIG. 2, the separation trench 11a partly surrounds the piezoelectric element 3 laterally, i.e. in this case, from three sides.

The separation trench 11a prevents crosstalk to adjacent volume acoustic devices 100. Together with the dielectric layer 7 immediately surrounding it, the piezoelectric resonator core forms a peninsula or half mesa which is delimited by the separation trench 11a.

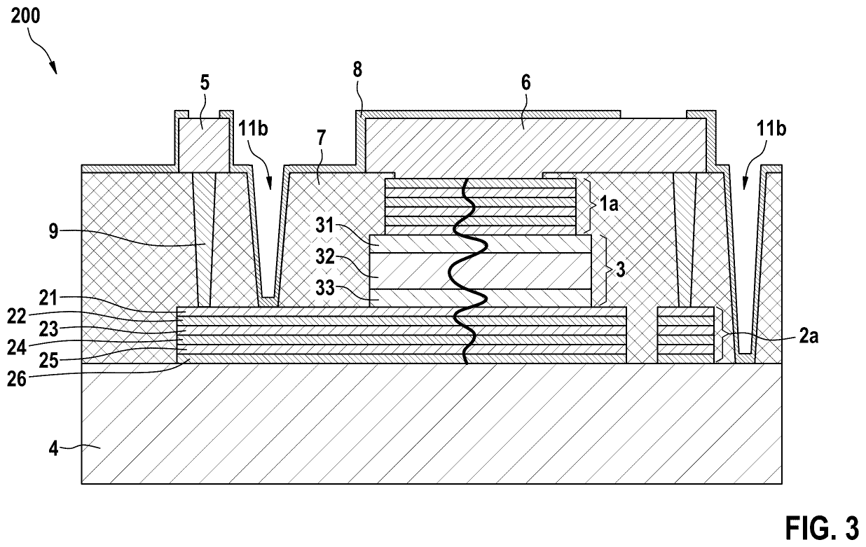

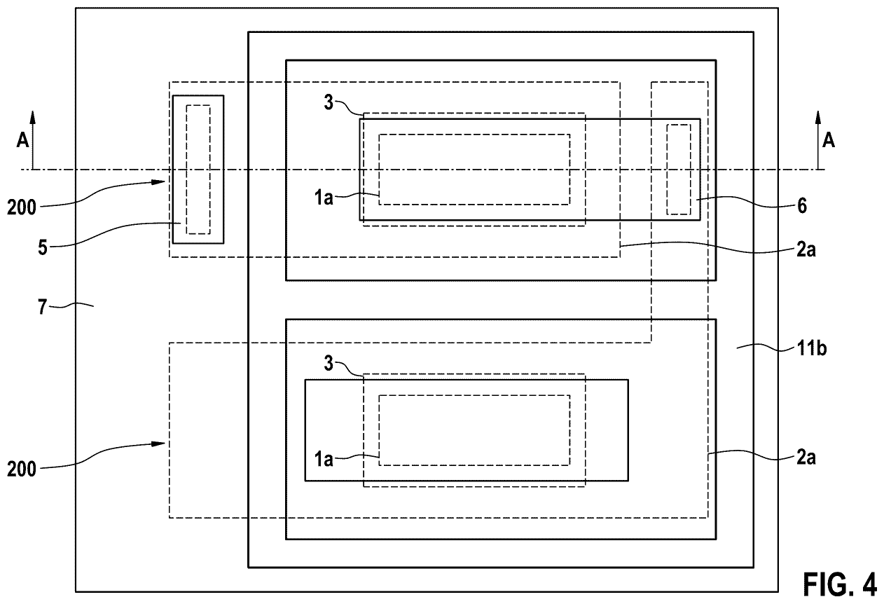

FIG. 3 shows a cross-sectional view of a further volume acoustic device 200 and FIG. 4 shows a corresponding plan view. In contrast to the volume acoustic device 100 shown in FIGS. 1 and 2, in this embodiment the separation trench 11b completely surrounds the piezoelectric element 3 laterally, i.e. from all four sides. Together with the dielectric layer 7 immediately surrounding it, the piezoelectric resonator core thus forms an island or mesa which is delimited by the separation trench 11b.

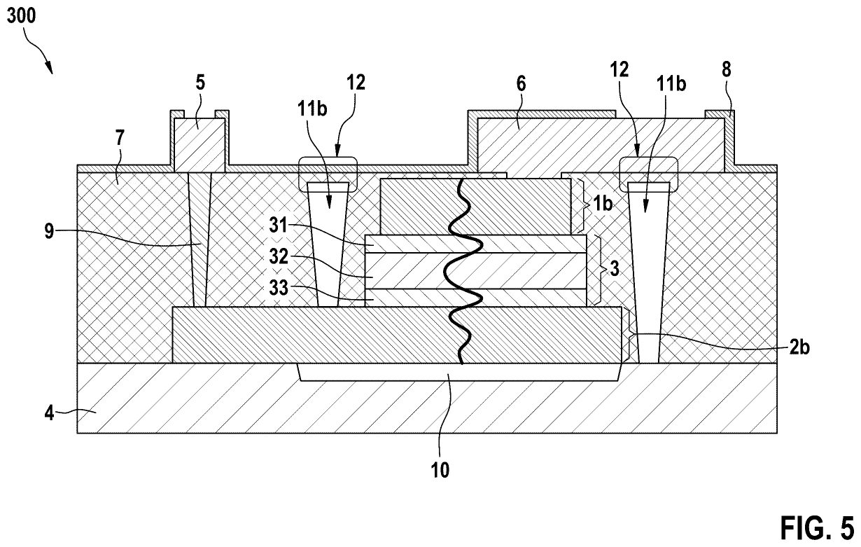

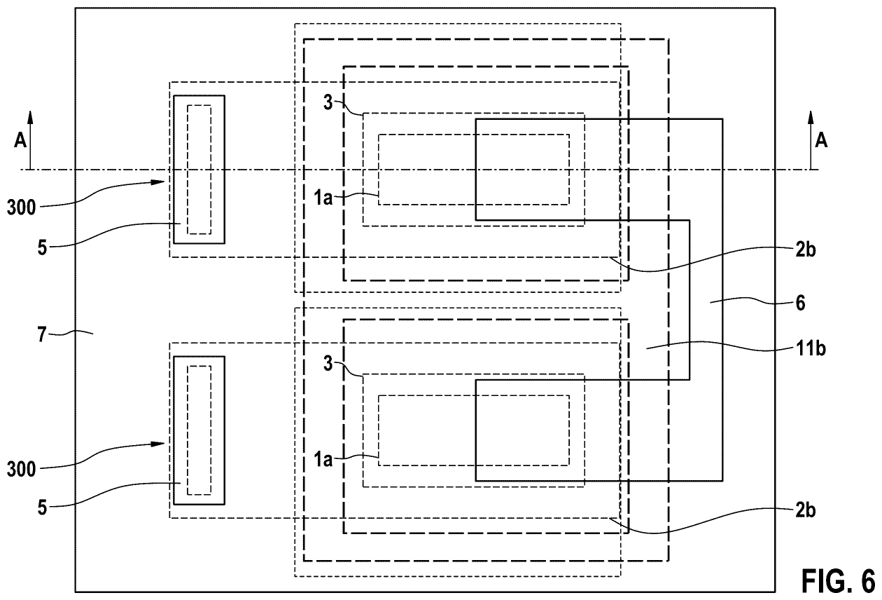

FIG. 5 shows a cross-sectional view of a further volume acoustic device 300 and FIG. 6 shows a corresponding plan view. In contrast to the volume acoustic device 200 shown in FIGS. 3 and 4, the electrodes 1b, 2b provided here are not configured as acoustic Bragg reflectors. The second electrode 2b is underetched, which results in a cavity 10 that can be connected to the separation trench 11b. The thickness of the electrodes 1b, 2b matches the wavelength of the pass frequency. A membrane 12 bridges the separation trench 11b. A lead can also be configured such that it passes over and passes over the separation trench 11 by means of the membrane 12, at least in the region of the upper lead.

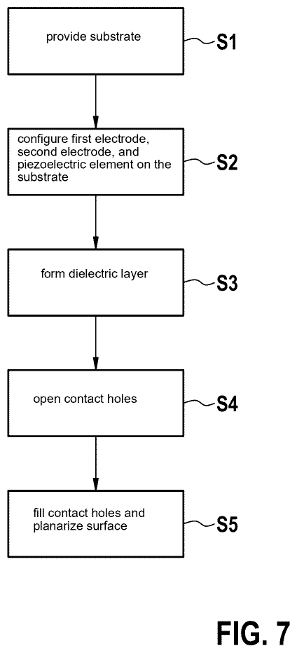

FIG. 7 shows a flow chart of a method for producing a volume acoustic device. In particular one of the volume acoustic devices 100 to 300 shown in FIGS. 1 to 6 can be produced.

In a first method step S1, a substrate 4 is provided, for example made of silicon.

In a second method step S2, a first electrode 1a, 1b, a second electrode 2a, 2b and a piezoelectric element 3 disposed between the first electrode 1a, 1b and the second electrode 2a, 2b are configured on the substrate 4. The second electrode 2a can be configured on the substrate 4 first. The piezoelectric element 3 is then configured on the second electrode 2a. Lastly, the first electrode 1a is configured on the piezoelectric element 3. The first and/or second electrode 1a, 1b, 2a, 2b can be configured as a Bragg reflector layer.

In a further method step S3, a dielectric layer 7 is formed, which surrounds the first electrode 1a, 1b, the second electrode 2a, 2b and the piezoelectric element 3. The dielectric layer 7 is planarized so that it has a substantially planar surface.

In a further method step S4, contact holes to the second electrode 2a, 2b are opened.

In a method step S5, the contact holes are filled and the surface is planarized. Optionally, a wiring layer is applied.

In a method step S6, at least one acoustic separation trench 11a, 11b is etched.

In a method step S7, a passivation layer 6 is formed.

The piezoelectric element 3 is configured such that a first electromagnetic signal fed into the first electrode 1a is converted to an acoustic signal in the piezoelectric element 3, and the acoustic signal is converted back into a second electromagnetic signal in the second electrode 2a. The piezoelectric element 3 preferably comprises at least two piezoelectric layers 31, 33 with the same polarity and at least one intermediate layer 32 disposed between the two piezoelectric layers 31, 33. Acoustic layer thicknesses of the piezoelectric layers 31, 33 and the intermediate layer 32 all correspond to an odd multiple (1×, 3×, . . . ) of half the acoustic wavelength of an acoustic signal to be transmitted.

1-11. (canceled)

12. A volume acoustic device, comprising
a first electrode and a second electrode;
a piezoelectric element disposed between the first electrode and the second electrode, wherein the piezoelectric element is configured such that a first electromagnetic signal fed into the first electrode is converted to an acoustic signal in the piezoelectric element and the acoustic signal is converted back into a second electromagnetic signal in the second electrode;
a dielectric layer which surrounds the first electrode, the second electrode, and the piezoelectric element, and has a substantially planar surface;
wherein at least one separation trench that at least partially surrounds the piezoelectric element is formed in the dielectric layer.

13. The volume acoustic device according to claim 12, further comprising:
at least one lead to the first electrode and/or the second electrode, wherein the at least one lead passes under the at least one separation trench.

14. The volume acoustic device according to claim 12, wherein the at least one separation trench is spanned by a membrane, wherein a lead to the first electrode and/or the second electrode is formed in the membrane.

15. The volume acoustic device according to claim 12, further comprising a cavity formed under the second electrode, wherein the cavity is fluidically connected to the separation trench.

16. The volume acoustic device according to claim 12, wherein the at least one separation trench is provided at least partly with a passivation layer.

17. The volume acoustic device according to claim 12, wherein the piezoelectric element includes at least two piezoelectric layers; and wherein acoustic layer thicknesses of the piezoelectric layers all correspond to an odd multiple of half an acoustic wavelength of the acoustic signal to be transmitted.

18. The volume acoustic device according to claim 12, wherein the first electrode and/or the second electrode are configured as an acoustic Bragg reflectors.

19. The volume acoustic device according to claim 12, wherein the piezoelectric element includes at least two piezoelectric layers and at least one intermediate layer (32) disposed between the at least two piezoelectric layers, wherein a material of the intermediate layer includes a dielectric.

20. A method for producing a volume acoustic device, comprising the following steps:
providing a substrate;
configuring a first electrode, a second electrode, and a piezoelectric element disposed between the first electrode and the second electrode, on the substrate, wherein the piezoelectric element is configured such that a first electromagnetic signal fed into the first electrode is converted to an acoustic signal in the piezoelectric element, and the acoustic signal is converted back into a second electromagnetic signal in the second electrode;
forming a dielectric layer which surrounds the first electrode, the second electrode, and the piezoelectric element, and has a substantially planar surface; and
forming at least one separation trench in the dielectric layer that at least partially surrounds the piezoelectric element.

21. The method according to claim 20, wherein the at least one separation trench is spanned by a membrane, wherein a lead to the first electrode and/or the second electrode is formed in the membrane.

22. The method according to claim 20, wherein a cavity is formed under the second electrode, wherein the cavity is fluidically connected to the separation trench.
